(19) United States
(12) Patent Application Publication
(10) Pub. No.: US 2025/0359100 A1
(43) Pub. Date: Nov. 20, 2025

(54) SEMICONDUCTOR DEVICE

(71) Applicant: Mitsubishi Electric Corporation, Tokyo (JP)

(72) Inventors: Kakeru OTSUKA, Tokyo (JP); Noboru MORIMOTO, Tokyo (JP); Kenji HARADA, Tokyo (JP)

(73) Assignee: Mitsubishi Electric Corporation, Tokyo (JP)

(21) Appl. No.: 19/070,513

(22) Filed: Mar. 4, 2025

(30) Foreign Application Priority Data
May 20, 2024 (JP) 2024-081900

(51) Int. Cl. H10D 12/00; H01L 23/29; H01L 23/31; H10D 62/10; H10D 64/00; H10D 64/60

(52) U.S. Cl. CPC H10D 12/415; H01L 23/291; H01L 23/293; H01L 23/3192; H10D 12/416; H10D 12/481; H10D 62/102; H10D 64/112; H10D 64/60

(57) ABSTRACT

A semiconductor device includes a transistor formed on a semiconductor substrate including an active region where the transistor is formed and a termination region surrounding the active region. The termination region includes a first interlayer insulating film on the semiconductor substrate, a second interlayer insulating film thereon, a wiring electrode electrically connected to a gate electrode of the transistor, a terminal electrode provided closer to the edge portion of the semiconductor substrate than the wiring electrode is, and a field plate electrode provided between the wiring electrode and the terminal electrode in plan view. The wiring electrode, the field plate electrode, and the terminal electrode are provided on the first interlayer insulating film. The field plate electrode is covered with the second interlayer insulating film. The field plate electrode has a smaller height than the wiring electrode and the terminal electrode.

### BACKGROUND

### Technical Field

The present disclosure relates to a semiconductor device and in particular to a semiconductor device having a termination structure.

### Description of the Background Art

Conventional semiconductor devices use a two-layer field plate as a termination structure to stabilize their potential as shown in, for example, FIG. 2 of Japanese Patent Application Laid-Open No. 2010-245281 (Patent Document 1), the two-layer field plate including a lower field plate provided in an interlayer insulating film and an upper field plate provided on the interlayer insulating film. However, the upper field plate includes a thick plate electrode and has a large cross-sectional area that is stressed in a horizontal direction.

Specifically, while a semiconductor device is packaged by sealing with a resin after bonding of wiring or the like to a semiconductor chip, the sealed resin has properties of expanding and contracting with heat. The expansion and contraction of the resin applies horizontal stress to the termination region of the semiconductor chip. When stressed in the horizontal direction, electrodes provided on the interlayer insulating film, including the plate electrode, can slide more easily in the horizontal direction. If the electrodes slide and come in contact with an electrode such as a gate line that has a potential different from that of the plate electrode, a short circuit may occur between the plate electrode and the gate line and result in a decrease in the reliability of the semiconductor device.

### SUMMARY

It is an object of the present disclosure to provide a semiconductor device with improved reliability while suppressing the occurrence of short-circuits between electrodes.

A semiconductor device according to the present disclosure is a semiconductor device including a transistor formed on a semiconductor substrate. The semiconductor substrate includes an active region in which the transistor is formed, and a termination region surrounding the active region. The termination region includes an first interlayer insulating film provided on the semiconductor substrate, a second interlayer insulating film provided on the first interlayer insulating film, a wiring electrode electrically connected to a gate electrode of the transistor, a terminal electrode provided closer to an edge portion of the semiconductor substrate than the wiring electrode is, and a field plate electrode provided between the wiring electrode and the terminal electrode in plan view. The wiring electrode, the field plate electrode, and the terminal electrode are provided on the first interlayer insulating film. The field plate electrode is covered with the second interlayer insulating film. The wiring electrode, the field plate electrode covered with the second interlayer insulating film, and the terminal electrode are covered with a protective film. The field plate electrode has a smaller height than the wiring electrode and the terminal electrode.

In the semiconductor device according to the present disclosure, only the field plate electrode having a lower height than the wiring electrode and the terminal electrode exists between the wiring electrode and the terminal electrode. Thus, even if the wiring electrode slides in the horizontal direction when the termination region is stressed in the horizontal direction, the reliability of the semiconductor device will not decrease due to the absence of such electrodes that come in contact with the wiring electrode.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view showing a semiconductor device that is as an RC-IGBT.

FIG. 2 is a sectional view of a boundary portion between an IGBT region and a termination region in the semiconductor device according to Embodiment 1.

FIG. 3 is a sectional view of a boundary portion between an IGBT region and a termination region in a semiconductor device according to Embodiment 2.

FIG. 4 is a sectional view showing a configuration of the IGBT region.

FIG. 5 is a sectional view oof a boundary portion between an IGBT region and a termination region in a semiconductor device according to Embodiment 3.

FIG. 6 is a sectional view of a boundary portion between an IGBT region and a termination region in a semiconductor device according to Variation 1 of Embodiment 3.

FIG. 7 is a sectional view of a boundary portion between an IGBT region and a termination region in a semiconductor device according to Variation 2 of Embodiment 3.

FIG. 8 is a sectional view of a boundary portion between an IGBT region and a termination region in a semiconductor device according to Embodiment 4.

FIG. 9 is a sectional view of a boundary portion between an IGBT region and a termination region in a semiconductor device according to Embodiment 5.

FIG. 10 is a sectional view of a boundary portion between an IGBT region and a termination region in a semiconductor device according to Embodiment 6.

FIG. 11 is a sectional view of a boundary portion between an IGBT region and a termination region in a semiconductor device according to Embodiment 7.

FIG. 12 is a sectional view of a boundary portion between an IGBT region and a termination region in a semiconductor device according to Embodiment 8.

FIG. 13 is a sectional view of a boundary portion between an IGBT region and a termination region in a semiconductor device according to Variation 1 of Embodiment 8.

FIG. 14 is a sectional view of a boundary portion between an IGBT region and a termination region in a semiconductor device according to Variation 2 of Embodiment 8.

FIG. 15 is a sectional view of a boundary portion between an IGBT region and a termination region in a semiconductor device according to Embodiment 9.

FIG. 16 is a sectional view of a boundary portion between an IGBT region and a termination region in a semiconductor device according to Embodiment 10.

FIG. 17 is a sectional view showing a variation of a field plate electrode.

FIG. 18 is a sectional view showing a variation of the field plate electrode.

FIG. 19 is a sectional view of a boundary portion between an IGBT region and a termination region in a semiconductor device according to Embodiment 11.

### DESCRIPTION OF THE PREFERRED EMBODIMENTS

### Introduction

In the following description, n and p types indicate semiconductor conductivity types, and the present disclosure is described with a first conductivity type as an n type and a second conductivity type as a p type. However, the first conductivity type may be described as a p type, and the second conductivity type may be described as an n type. Moreover, an n⁻ type indicates a lower impurity concentration than the n type, and an n⁺-type indicates a higher impurity concentration than the n type. Similarly, a p⁻ type indicates a lower impurity concentration than the p type, and a p⁺ type indicates a higher impurity concentration than the p type.

Since the drawings are illustrated in schematic form, mutual relationships of sizes and positions of images shown in different drawings are not always accurate and may be changed as appropriate. In the following description, identical constituent elements are given the same reference signs and assumed to have the same name and function. Thus, detailed descriptions of the constituent elements may be omitted in some cases.

In the following description, terms used to mean specific positions and directions such as “upper,” “lower,” “side,” “bottom,” “front,” and “back” are merely used for convenience's sake in order to facilitate understanding of the contents of embodiments, and do not relate to actual positions and directions at the time of actual implementation.

While the following description takes, as an example, a case in which the present disclosure is applied to a reverse conducting IGBT (RC-IGBT) in which insulated-gate bipolar transistors (IGBTs) and freewheeling diodes (FWDs) are provided on a common semiconductor substrate, the application of the present disclosure is not limited to the RC-IGBT, and the present disclosure is also applicable to, for example, IGBTs and MOS field transistors (MOSFETs).

### Explanation of RC-IGBT

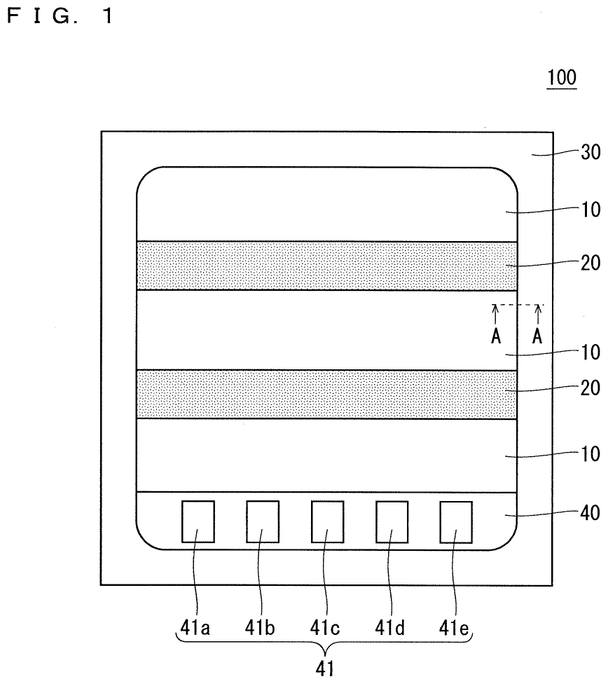

FIG. 1 is a plan view showing an RC-IGBT 100. The RC-IGBT 100 shown in FIG. 1 is a transistor in which IGBT regions 10 and diode regions 20 are arranged side by side in stripes, and is hereinafter simply referred to as a “stripe-type” transistor. Although RC-IGBTs called “island-type” also exist in which a plurality of diode regions 20 are arranged in longitudinal and lateral directions and IGBT regions 10 are arranged around the diode regions 20, the present disclosure is applicable to either layout pattern and therefore illustration and descriptions of such “island-type” transistor shall be omitted.

In FIG. 1, the IGBT regions 10 and the diode regions 20 extend from one end side to the other end side of the RC-IGBT 100 and are alternately arranged in stripes in a direction orthogonal to the direction of extension of the IGBT regions 10 and the diode regions 20. FIG. 1 shows a configuration in which three IGBT regions 10 and two diode regions are arranged and every diode region 20 is sandwiched between two IGBT regions 10. However, the number of IGBT regions 10 and the number of diode regions 20 are not limited to this example. For example, the number of IGBT regions 10 may be greater than or equal to three or less than or equal to three, and the number of diode regions 20 may also be greater than two or more or less than two or less. Other configurations are also possible, such as where the locations of the IGBT regions 10 and the locations of the diode regions 20 in FIG. 1 are interchanged or where every IGBT region 10 is sandwiched between two diode regions 20. A configuration is also possible in which each one IGBT region 10 and each one diode region 20 are arranged adjacent to each other.

As shown in FIG. 1, a pad region 40 is provided adjacent to the IGBT region 10 that is arranged at the bottom in the plane of the drawing. The pad region 40 is an area in which control pads 41 are arranged in order to control the RC-IGBT 100. The IGBT regions 10 and the diode regions 20 are collectively referred to as a cell region. Around an area that combines the cell region and the pad region 40, a termination region 30 is provided in order to maintain a withstand voltage of the RC-IGBT 100.

The present disclosure relates to a termination structure that is provided in the termination region 30 to maintain the withstand voltage, and specific examples of the termination structure will be described with reference to embodiments.

The control pads 41 may, for example, be a current sensing pad 41a, a Kelvin emitter pad 41b, a gate pad 41c, and temperature sensing diode pads 41d and 41e. The current sensing pad 41a is a control pad for detecting current flowing through the cell region of the RC-IGBT 100, and is also a control pad that is electrically connected to some IGBT cells or some diode cells in the cell region so as to pass a current that is a fraction of several to several tens of thousands of a current that flows through the entire cell region of the RC-IGBT 100 at the time of the current flowing through the cell region.

The Kelvin emitter pad 41b and the gate pad 41c are control pads to which a gate driving voltage is applied in order to control turn on and off of the RC-IGBT 100. The Kelvin emitter pad 41b is electrically connected to p-type base layers of the IGBT cells, and the gate pad 41c is electrically connected to gate trench electrodes of the IGBT cells. The Kelvin emitter pad 41b and the p-type base layers may be electrically connected to each other via a p⁺-type contact layer. The temperature sensing diode pads 41d and 41e are control pads that are electrically connected to anodes and cathodes of temperature sensing diodes provided in the RC-IGBT 100. These temperature sensing diode pads measure the temperature of the RC-IGBT 100 by measuring voltage between anodes and cathode of temperature sensing diodes (not shown) provided in the cell region.

### Embodiment 1

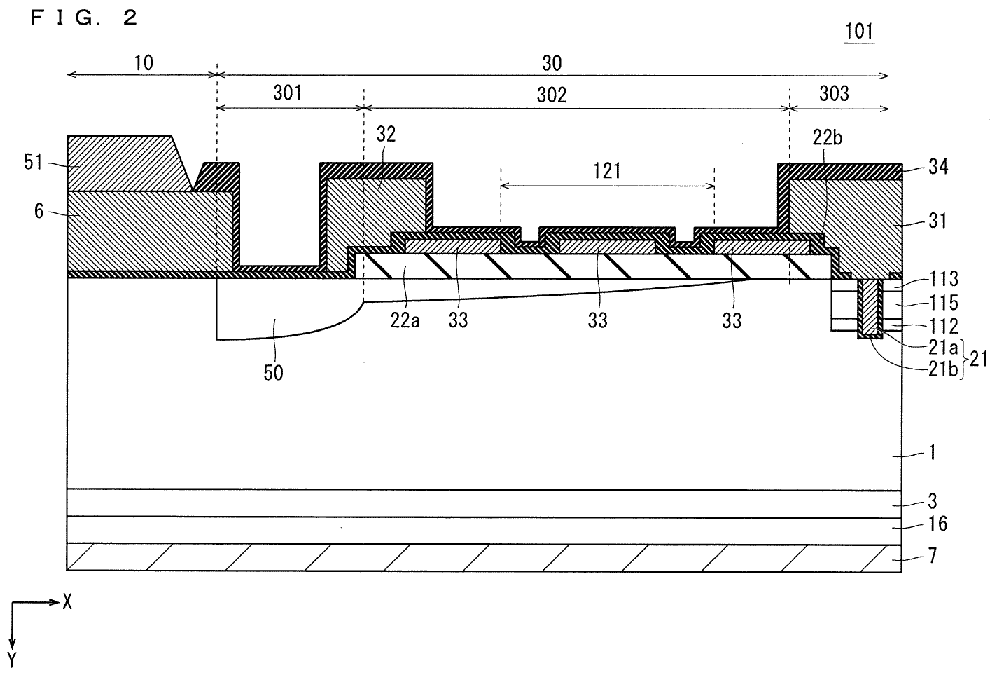

In the following description, each embodiment is described with reference to a sectional view of the RC-IGBT 100 taken in the direction of an arrow indicated by a broken line A-A in FIG. 1. In Embodiment 1 shown in FIG. 2, the RC-IGBT 100 is described as an RC-IGBT 101 for the sake of convenience. As shown in FIG. 2, the termination region 30 is sectioned into a field relieving region 301, a RESURF region 302, and a channel stopper region 303 in order from the side closer to the IGBT region 10.

As shown in FIG. 2, the termination region 30 of the RC-IGBT 101 according to Embodiment 1 includes an n⁻-type drift layer 1 between first and second main surfaces of a semiconductor substrate. First and second main surfaces of the termination region 30 are the same as first and second main surfaces of each IGBT region 10, which will be described later. The n⁻-type drift layer 1 in the termination region 30 and the n⁻-type drift layer 1 in each IGBT region 10 have the same configuration and are formed continuously and integrally.

The n⁻-type drift layer 1 is a semiconductor layer that may contain, for example, arsenic (As) or phosphorus (P) as an n-type impurity and has an n-type impurity concentration of 1.0×10¹²/cm³ to 1.0×10¹⁵/cm³.

On the first main surface side of the n⁻-type drift layer 1, a p-type terminal well layer 50 is provided between the n⁻-type drift layer 1 and the first main surface of the semiconductor substrate. The p-type terminal well layer 50 is a semiconductor layer that may contain, for example, boron (B) or aluminum (Al) as a p-type impurity, has a p-type impurity concentration of 1.0×10¹⁴/cm³ to 1.0×10¹⁹/cm³, and is provided to surround the cell region including the IGBT regions 10 and the diode regions 20. The p-type terminal well layer 50 has a variation of lateral doping (VLD) structure having a depth that gradually decreases toward the edge of the semiconductor substrate and that is approximately 6 μm at the deepest point.

On the outer edge side of the p-type terminal well layer 50, a trench is formed extending from the first main surface of the semiconductor substrate to the n⁻-type drift layer 1 through an n⁺-type channel stopper layer 113, a p-type channel stopper layer 115, and an n-type channel stopper layer 112. In the trench, a trench electrode 21a formed of polysilicon is provided via an insulating film 21b to form a floating trench 21. The n⁺-type channel stopper layer 113, the p-type channel stopper layer 115, and the n-type channel stopper layer 112 are formed in the same steps as an n⁺-type source layer 13, a p-type base layer 15, and an n-type carrier stored layer 2, which are provided in the IGBT region 10 described later. The trench insulating film 21b and the trench electrode 21a are formed in the same steps as gate trench insulating films 11b and gate trench electrodes 11a, which are provided in the IGBT region 10 described later, but the trench electrode 21a is electrically floating. Although FIG. 2 is a sectional view of one IGBT region 10 and the termination region 30, which is taken in the direction of the arrow indicated by the broken line A-A in FIG. 1, a section taken from FIG. 1 may be a section view of one diode region 20 and the termination region 30. The cell region including the IGBT regions 10 and the diode regions 20 may also be referred to as an active region.

On the second main surface side of the n⁻-type drift layer 1, an n-type buffer layer 3 is provided with a higher n-type impurity concentration than the n⁻-type drift layer 1. The n-type buffer layer 3 may be formed by, for example, implanting either or both of phosphorus (P) and proton (H⁺). The n-type buffer layer 3 has an n-type impurity concentration of 1.0×10¹²/cm³ to 1.0×10¹⁸/cm³.

On the second main surface side of the n-type buffer layer 3, a p-type collector layer 16 is provided. The p-type collector layer 16 is a semiconductor layer that may contain, for example, boron or aluminum as a p-type impurity and has a p-type impurity concentration of 1.0×10¹⁶/cm³ to 1.0×10²⁰/cm³. The p-type collector layer 16 forms the second main surface of the semiconductor substrate. The p-type collector layer 16 extends from the IGBT region 10 and may also be referred to as a p-type terminal collector layer in order to distinguish from the p-type collector layer in the IGBT region 10.

On the second main surface side of the p-type collector layer 16, a collector electrode 7 is provided. The collector electrode 7 may be formed of an aluminum alloy or may be formed of an aluminum alloy and a plating film. The collector electrode 7 is in ohmic contact with the p-type collector layer 16 and electrically connected to the p-type collector layer 16.

In FIG. 2, the semiconductor substrate ranges from the p-type terminal well layer 50 to the p-type collector layer 16. In FIG. 2, the upper end of the p-type terminal well layer 50 in the plane of the drawing is referred to as the first main surface of the semiconductor substrate, and the lower end of the p-type collector layer 16 in the plane of the drawing is referred to as the second main surface of the semiconductor substrate. The first main surface of the semiconductor substrate is a main surface on the front surface side of the RC-IGBT 101, and the second main surface of the semiconductor substrate is a main surface on the rear surface side of the RC-IGBT 101.

In the termination region 30, as shown in FIG. 2, an interlayer insulating film 22a (first interlayer insulating film) having a thickness of approximately 900 nm is provided on the first main surface of the semiconductor substrate, and a channel stopper electrode 31, a gate line 32 (wiring electrode), and field plate electrodes 33 are provided on the interlayer insulating film 22a. The field plate electrodes 33 may be formed of, for example, polysilicon or amorphous silicon and provided in the shape of a plurality of rings. The number of field plate electrodes 33 to be provided may be selected as appropriate according to the pressure-resistant design of the RC-IGBT 101.

The field plate electrodes 33 are covered with an interlayer insulating film 22b (second interlayer insulating film) having a thickness of approximately 500 nm, and the channel stopper electrode 31 and the gate line 32 are electrically isolated from the field plate electrodes 33 by the interlayer insulating film 22b. The interlayer insulating film 22b extends to under an emitter electrode 6 in the IGBT region 10.

Part of the channel stopper electrode 31, called a terminal electrode, is connected to the trench electrode 21a via a contact hole provided in the interlayer insulating film 22a.

The field plate electrodes 33 covered with the interlayer insulating film 22b, the channel stopper electrode 31, and the gate line 32 are covered with a silicon nitride film 34 provided as a first protective film and having a thickness of approximately 800 nm. The silicon nitride film 34 extends over the gate line 32 to above the edge portion of the emitter electrode 6 in the IGBT region 10. The silicon nitride film 34 may be configured as an insulating layer, or may be configured as two layers including an insulating layer (Si₃N₄) and a semi-insulating layer (semi-insulating silicon nitride: SInSiN).

On the emitter electrode 6, a solder layer 51 is provided for joining with an external electrode, and the silicon nitride film 34 extends up to a position at which it does not come in contact with the solder layer 51. The edge portion of the silicon nitride film 34 on the emitter electrode 6 is formed to be inclined 60 degrees or less toward the surface of the emitter electrode 6.

The field plate electrodes 33 are provided between the gate line 32 and the channel stopper electrode 31. In FIG. 2, three field plate electrodes 33 are provided at intervals, and a region between the leftmost and rightmost field plate electrodes 33 is referred to as an inter-field-plate region 121. No electrodes other than the field plate electrodes 33 are provided at least in this inter-field-plate region 121.

Accordingly, even if the gate line 32 slides in the horizontal direction when the termination region 30 is stressed in the horizontal direction due to expansion and contraction of a sealing resin used to seal the RC-IGBT 101 and when the termination region 30 is stressed in the horizontal direction from the solder layer 51 due to heating of the solder layer 51 for joining with an external electrode, the reliability of the RC-IGBT 101 as a semiconductor device will not decrease because there are no electrodes that come in contact with the gate line 32.

Besides, since the termination region 30 is covered with the silicon nitride film 34, it is possible to suppresses a reduction in withstand voltage caused by moisture ingress from the outside.

Since the silicon nitride film 34 has an inclined edge portion, horizontal stress applied to the silicon nitride film 34 is dispersed in the horizontal and vertical directions, i.e., X and Y directions. This alleviates the stress applied to the silicon nitride film 34.

Here, the field plate electrodes 33 have a thickness of less than or equal to 1 μm, e.g., 800 nm, and is thinner than the gate line 32 having a thickness of approximately 3 μm to 5 μm. This prevents deformation of the filed plate electrodes 33 due to external stress. Note that the emitter electrode 6 and the channel stopper electrode 31 also have thicknesses of approximately 3.6 μm. Like the collector electrode 7, the channel stopper electrode 31, the gate line 32, and the emitter electrode 6 may be formed of an aluminum alloy or may be formed of an aluminum alloy and a plating film.

### Embodiment 2

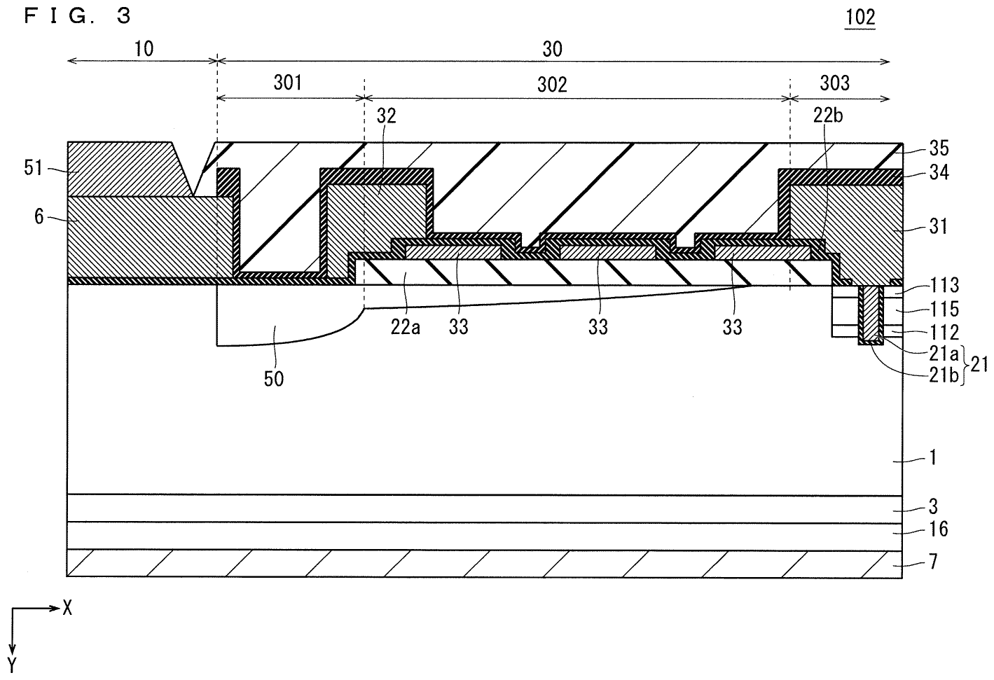

FIG. 3 is a sectional view showing a configuration of an RC-IGBT 102 according to Embodiment 2 and corresponds to the sectional view taken in the direction of the arrow indicated by the broken line A-A in FIG. 1. In the RC-IGBT 102, as shown in FIG. 3, a polyimide film 35 having a thickness of approximately 9 μm is provided as a second protective film to cover over the silicon nitride film 34. In FIG. 3, constituent elements that are identical to those of the RC-IGBT 101 described with reference to FIG. 2 are given the same reference signs, and redundant descriptions thereof shall be omitted.

The polyimide film 35 extends to above the edge portion of the emitter electrode 6 and is formed to be inclined 60 degrees or less toward the surface of the emitter electrode 6.

Like the RC-IGBT 101 according to Embodiment 1, the RC-IGBT 102 achieves the effect of suppressing a reduction in reliability as a semiconductor device even if stressed in the horizontal direction. In conjunction with this, the termination region 30 further covered with the polyimide film 35 improves adhesion to the sealing resin used to seal the RC-IGBT 102 and improves the reliability of the RC-IGBT 102 as a semiconductor device.

Since the polyimide film 35 has an inclined edge portion on the emitter electrode 6, horizontal stress applied to the polyimide film 35 is dispersed in the horizontal and vertical directions, i.e., the X and Y directions. This alleviates the stress applied to the polyimide film 35.

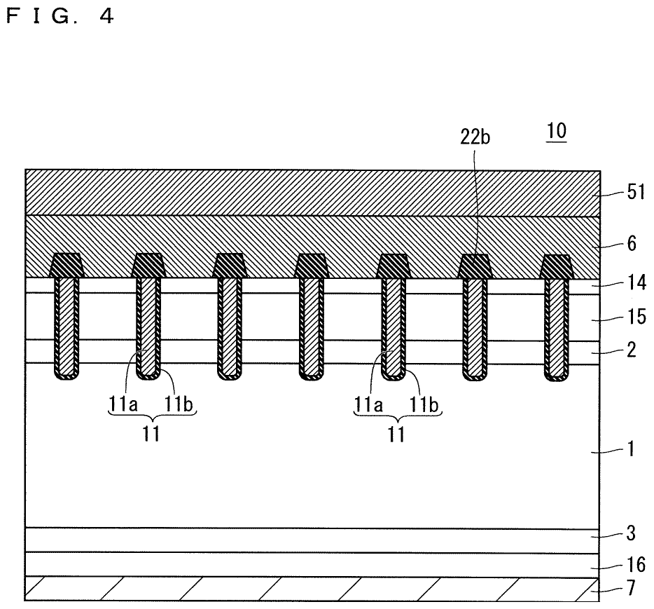

Now, a configuration of the IGBT regions 10 is described with reference to FIG. 4. FIG. 4 is a sectional view showing the configuration of the IGBT region 10 in the sectional view taken in the direction of the arrow indicated by the broken line A-A in FIG. 1. In the IGBT region 10, as shown in FIG. 4, the n-type carrier stored layer 2 having a higher n-type impurity concentration than the n⁻-type drift layer 1 is provided on the first main surface side of the n⁻-type drift layer 1. The n-type carrier stored layer 2 is a semiconductor layer that may contain, for example, As or P as an n-type impurity and has an n-type impurity concentration of 1.0×10¹³/cm³ to 1.0×10¹⁷/cm³.

The p-type base layer 15 is provided on the first main surface side of the n-type carrier stored layer 2. The p-type base layer 15 is a semiconductor layer that may contain, for example, boron or aluminum as a p-type impurity and has a p-type impurity concentration of 1.0×10¹²/cm³ to 1.0×10¹⁹/cm³. The p-type base layer 15 is in contact with gate trench insulating films 11b of trench gates 11. On the first main surface side of the p-type base layer 15, a p⁺-type contact layer 14 is provided in contact with the gate trench insulating films 11b of the trench gates 11. The p⁺-type contact layer 14 configures the first main surface of the semiconductor substrate. Note that the p+-type contact layer 14 is a region having a higher p-type impurity concentration than the p-type base layer 15. There is also a region in which the n⁺-type source layer 13 is provided instead of the p+-type contact layer 14. The n⁺-type source layer 13 is a semiconductor layer that may contain, for example, arsenic or phosphorus as an n-type impurity and has an n-type impurity concentration of 1.0×10¹⁷/cm³ to 1.0×10²⁰/cm³.

Trenches are formed extending from the first main surface of the semiconductor substrate to the n⁻-type drift layer 1 through the p+-type contact layer 14 and the p-type base layer 15. The trench gates 11 are configured by providing the gate trench electrodes 11a within the trenches via the gate trench insulating films 11b. The gate trench electrodes 11a are electrically connected to the gate line 32 in the termination region 30 and receives the application of the gate driving voltage input from the gate pad 41c via the gate line 32. The gate trench electrodes 11a are opposed to the n⁻-type drift layer 1 via the gate trench insulating films 11b. The interlayer insulating film 22b is provided on the gate trench electrodes 11a of the trench gates 11, and the emitter electrode 6 and the p⁺-type contact layer 14 are electrically connected to each other via a contact hole provided in the interlayer insulating film 22b.

On the second main surface side of the n⁻-type drift layer 1, the n-type buffer layer 3, the p-type collector layer 16, and the collector electrode 7 are provided in the same manner as in the termination region 30.

The gate trench electrodes 11a may be formed by depositing n- or p-type impurity-doped polysilicon or amorphous silicon by CVD within the trenches each having an inner wall on which the gate trench insulating film 11b is formed.

Thus, at the same time when the gate trench electrodes 11a are formed, the field plate electrodes 33 are formed in the termination region 30.

In the case where the field plate electrodes 33 are formed of polysilicon and the emitter electrode 6 is formed of an aluminum alloy or the like, the field plate electrodes 33 have a Young's modulus of approximately 130 GPa, and the emitter electrode 6 has a Young's modulus of approximately 60 GPa. Since the field plate electrodes 33 have a higher Young's modulus than the emitter electrode 6, the field plate electrode 33 becomes more resistant to deformation caused by external stress.

### Embodiment 3

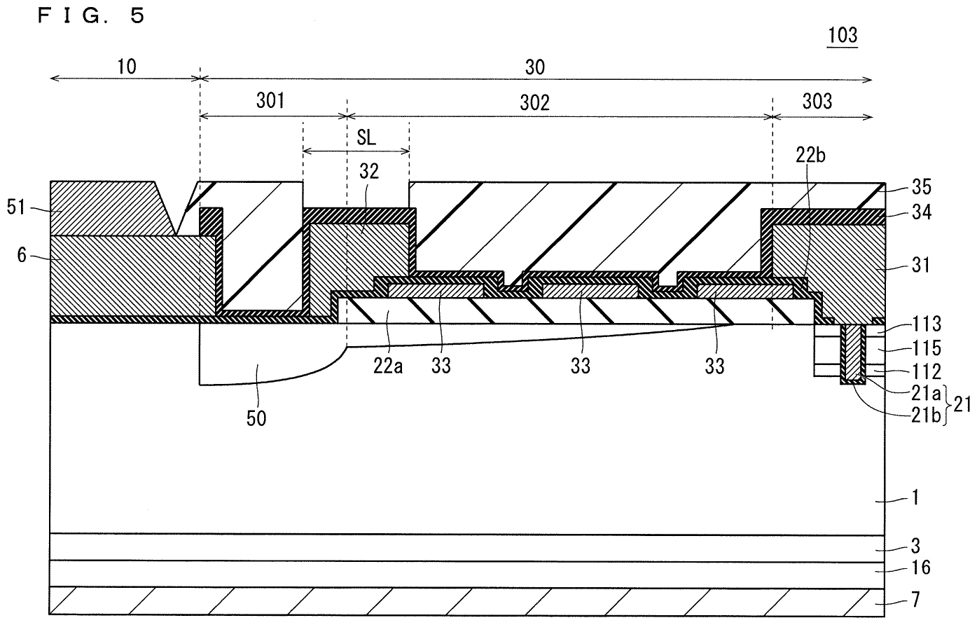

FIG. 5 is a sectional view showing a configuration of an RC-IGBT 103 according to Embodiment 3 and corresponds to the sectional view taken in the direction of the arrow indicated by the broken line A-A in FIG. 1. In the RC-IGBT 103, as shown in FIG. 5, a slit SL is formed in the polyimide film 35 above the gate line 32. In FIG. 5, constituent elements that are identical to those of the RC-IGBT 101 described with reference to FIG. 2 are given the same reference signs, and redundant descriptions thereof shall be omitted.

The slit SL has a width equivalent to the width of the gate line 32 and is formed by opening the polyimide film 35 above the gate line 32 by etching or any other technique so as not to open the silicon nitride film 34. Although the slit SL in FIG. 5 has a width equivalent to the width of the gate line 32, the width of the slit SL may be set in the range of approximately 50 μm to 70 μm that are magnitudes allowing for stable formation during a manufacturing process, but may be set to a greater value.

The presence of the slit SL alleviates the horizontal stress applied from the side of the IGBT region 10, i.e., the active region side, to the polyimide film 35 and in particular the stress applied from the solder layer 51, and improves the reliability of the polyimide film 35. The presence of the slit SL above the gate line 32 improves the reliability of the RC-IGBT 103 as a semiconductor device while the field plate electrodes 33 are protected by the polyimide film 35 and the silicon nitride film 34.

### Variation 1

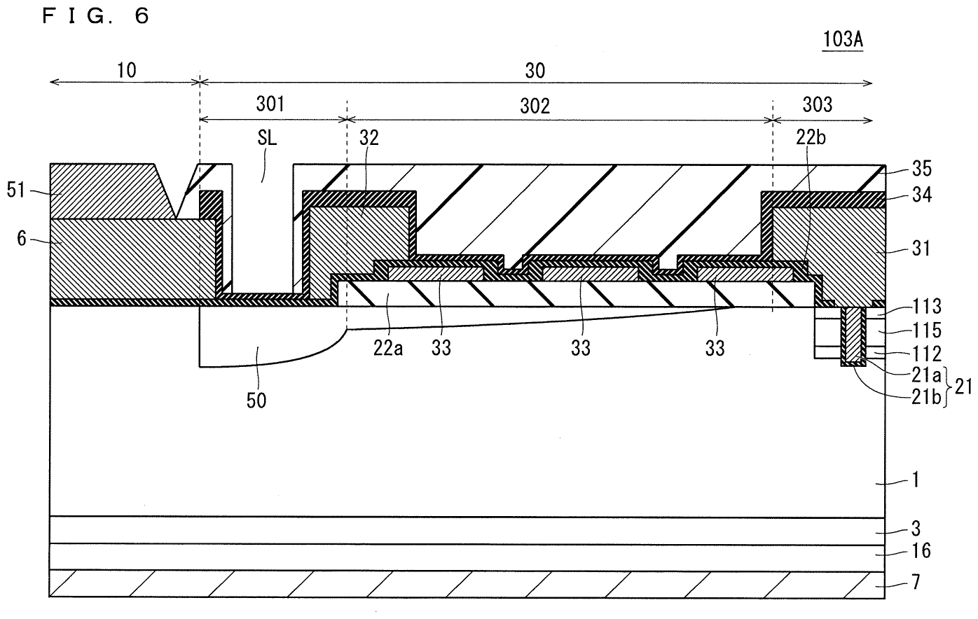

FIG. 6 is a sectional view showing a configuration of an RC-IGBT 103A according to Variation 1 of Embodiment 3 and corresponds to the sectional view taken in the direction of the arrow indicated by the broken line A-A in FIG. 1. In the RC-IGBT 103A, as shown in FIG. 6, the slit SL is formed in the polyimide film 35 located in a region between the gate line 32 and the emitter electrode 6.

The slit SL has a width that does not exceed across the region between the gate line 32 and the emitter electrode 6 and is formed by opening the polyimide film 35 so as not to open the silicon nitride film 34. The width of the slit SL is adjusted to the interval between the gate line 32 and the emitter electrode 6 and may be set in the range of approximately 50 μm to 70 μm, but may also be increased along with an increase in the interval between the gate line 32 and the emitter electrode 6.

The presence of the slit SL alleviates the horizontal stress applied from the side of the IGBT region 10, i.e., the active region side, to the polyimide film 35 and in particular the stress applied from the solder layer 51, and improves the reliability of the polyimide film 35. The provision of the slit SL in the region other than the region where the field plate electrodes 33 are provided improves the reliability of the RC-IGBT 103A as a semiconductor device while the field plate electrodes 33 are protected by the polyimide film 35 and the silicon nitride film 34.

### Variation 2

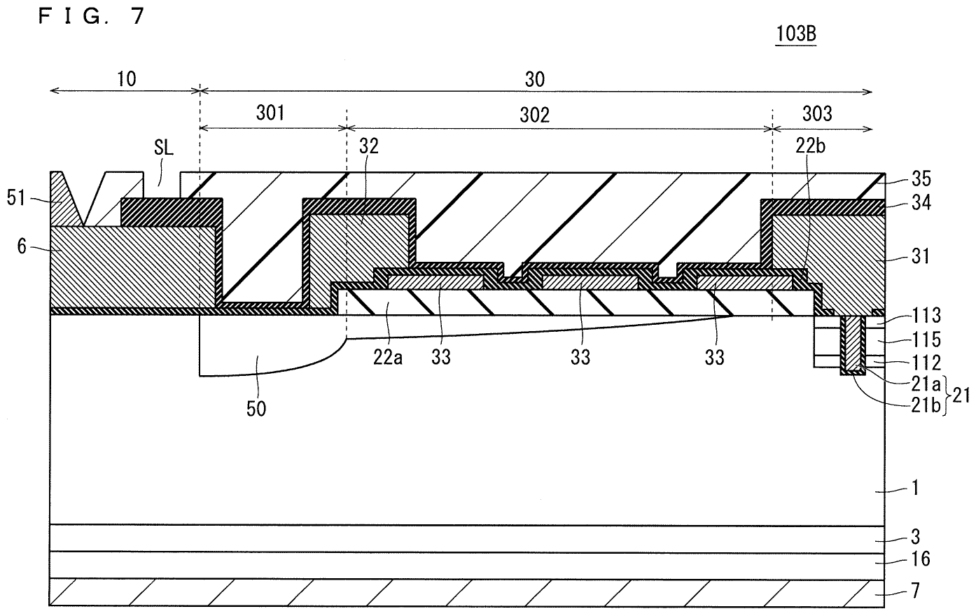

FIG. 7 is a sectional view showing a configuration of an RC-IGBT 103B according to Variation 2 of Embodiment 3 and corresponds to the sectional view taken in the direction of the arrow indicated by the broken line A-A in FIG. 1. In the RC-IGBT 103B, as shown in FIG. 7, the silicon nitride film 34 extends across the edge portion of the emitter electrode 6 in the IGBT region 10, i.e., the active region, and the polyimide film 35 is provided to cover over the silicon nitride film 34. The slit SL is formed in the polyimide film 35 above the emitter electrode 6.

The slit SL is formed by opening the polyimide film 35 on the silicon nitride film 34 so as not to open the silicon nitride film 34. The width of the slit SL may be set in the range of approximately 50 μm to 70 μm that are magnitudes allowing for stable formation during a manufacturing process, but may be set to a greater value. In that case, the silicon nitride film 34 is further extended on the emitter electrode 6.

The presence of the slit SL alleviates the horizontal stress applied from the side of the IGBT region 10, i.e., the active region side, to the polyimide film 35 and in particular the stress applied from the solder layer 51, and improves the reliability of the polyimide film 35. The provision of the slit SL in the region other than the region where the field plate electrodes 33 are provided improves the reliability of the RC-IGBT 103B as a semiconductor device while the field plate electrodes 33 are protected by the polyimide film 35 and the silicon nitride film 34.

### Embodiment 4

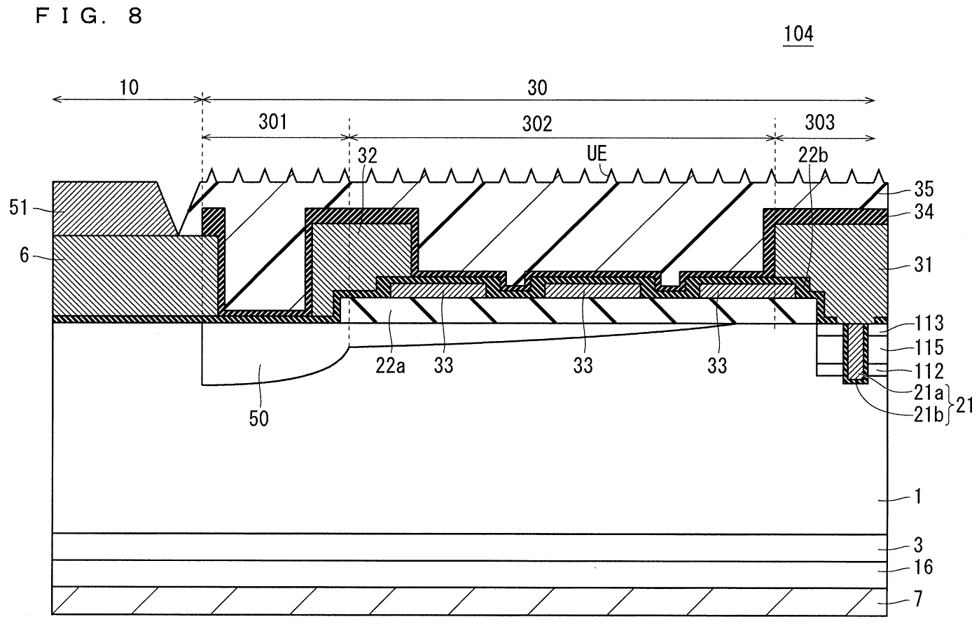

FIG. 8 is a sectional view showing a configuration of an RC-IGBT 104 according to Embodiment 4 and corresponds to the sectional view taken in the direction of the arrow indicated by the broken line A-A in FIG. 1. In the RC-IGBT 104, as shown in FIG. 8, a plurality of projections UE are formed on the surface of the polyimide film 35. In FIG. 8, constituent elements that are identical to those of the RC-IGBT 101 described with reference to FIG. 2 are given the same reference signs, and redundant descriptions thereof shall be omitted.

The projections UE protrudes to a height of approximately 10 nm from the surface of the polyimide film 35, so that the polyimide film 35 has an uneven surface. When the RC-IGBT 104 is sealed with a sealing resin, the presence of the projections UE further improves the adhesion of the polyimide film 35 to the sealing resin. This reduces the occurrence of clearance between the sealing resin and the polyimide film 35 and improves the reliability of the RC-IGBT 104 as a semiconductor device.

The uneven surface of the polyimide film 35 is formed because a process performed on the rear surface of the RC-IGBT 104 involves a process of cleaning the front surface, and this cleaning process roughens the surface of the polyimide film 35 and produces irregularities on the surface of the polyimide film 35.

### Embodiment 5

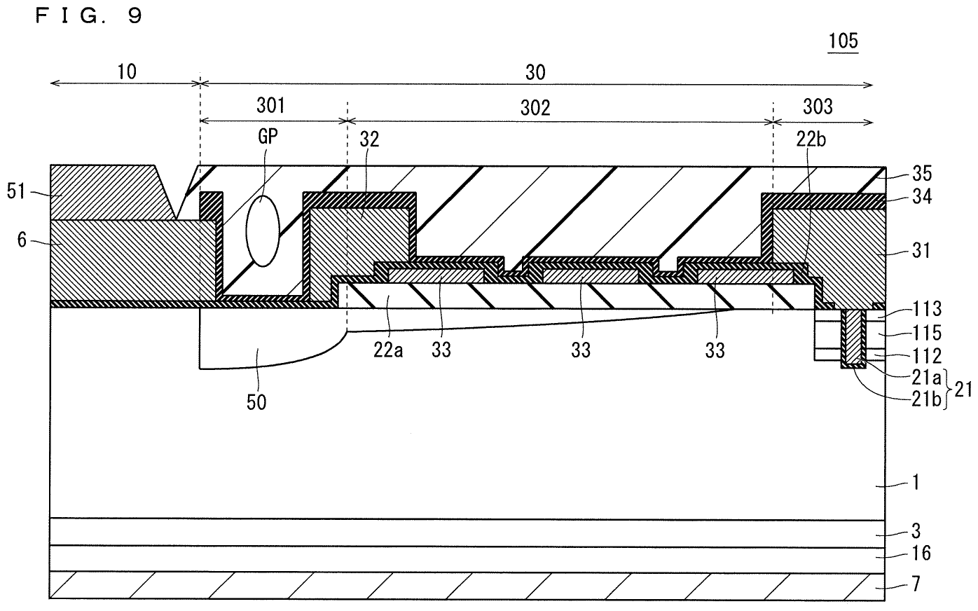

FIG. 9 is a sectional view showing a configuration of an RC-IGBT 105 according to Embodiment 5 and corresponds to the sectional view taken in the direction of the arrow indicated by the broken line A-A in FIG. 1. In the RC-IGBT 105, as shown in FIG. 9, a cavity GP is formed in the polyimide film 35 provided in the region between the gate line 32 and the emitter electrode 6.

The cavity GP has a width that does not exceed across the region between the gate line 32 and the emitter electrode 6 even at its maximum, and is formed in the polyimide film 35 so as not to reach to the silicon nitride film 34. The maximum width of the cavity GP is adjusted to the interval between the gate line 32 and the emitter electrode 6 and may be set in the range of approximately 50 μm to 70 μm, but may also be increased along with an increase in the interval between the gate line 32 and the emitter electrode 6.

The provision of the cavity GP alleviates the horizontal stress applied from the side of the IGBT region 10, i.e., the active region side, and in particular the stress applied from the solder layer 51, and improves the reliability of the polyimide film 35.

The provision of the cavity GP in the region other than the region where the field plate electrodes 33 are provided improves the reliability of the RC-IGBT 105 as a semiconductor device while the field plate electrodes 33 are protected by the polyimide film 35 and the silicon nitride film 34.

In the formation of the cavity GP, after the polyimide film 35 is formed to cover the silicon nitride film 34, an opening is formed by removing part of the polyimide film 35 where the cavity GP is to be formed, by etching or any other technique without penetrating the polyimide film 35. At this time, the conditions of etching may desirably be set such that the upper end of the opening becomes narrower than the bottom of the opening. Thereafter, the polyimide film 35 as a whole is heated and cured at a temperature of approximately 350° C., and the upper end of the opening is closed so as to form the cavity GP in the polyimide film 35.

### Embodiment 6

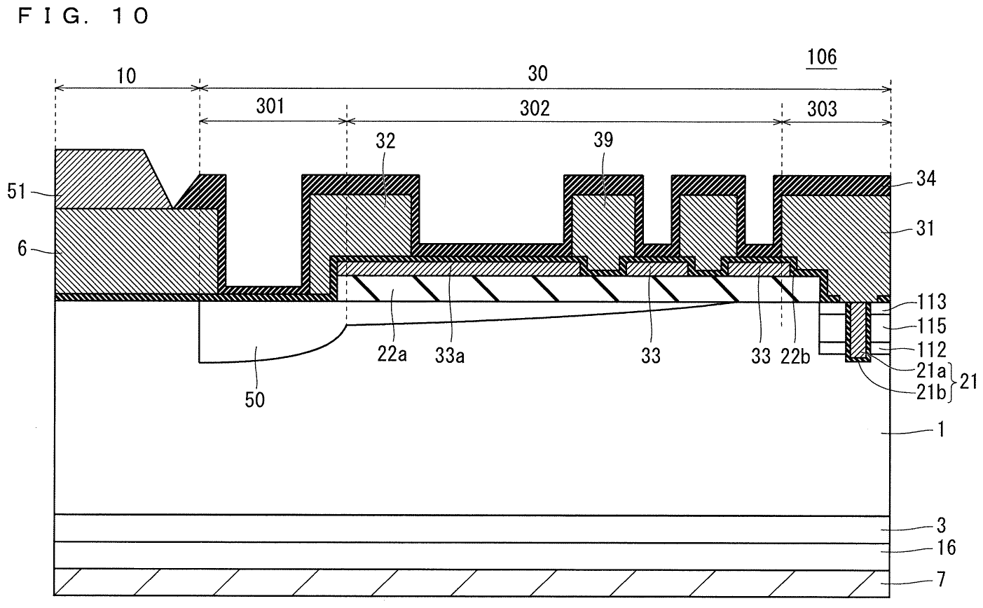

FIG. 10 is a sectional view showing a configuration of an RC-IGBT 106 according to Embodiment 6 and corresponds to the sectional view taken in the direction of the arrow indicated by the broken line A-A in FIG. 1. In FIG. 10, constituent elements that are identical to those of the RC-IGBT 101 described with reference to FIG. 2 are given the same reference signs, and redundant descriptions thereof shall be omitted.

In the termination region 30 of the RC-IGBT 106, as shown in FIG. 10, the channel stopper electrode 31, the gate line 32, the field plate electrodes 33, an active-region side field plate electrode 33a, and an upper field plate electrode 39 are provided on the interlayer insulating film 22a provided on the first main surface of the semiconductor substrate and having a thickness of approximately 900 nm. The field plate electrodes 33 and the active-region side field plate electrode 33a may be formed of, for example, polysilicon or amorphous silicon in the shape of a plurality of rings. The number of field plate electrodes 33 to be provided is selected as appropriate according to the pressure-resistant design of the RC-IGBT 106. The active-region side field plate electrode 33a is provided closest to the active region and formed wider than the field plate electrodes 33. The width of the active-region side field plate electrode 33a is two times or more the width of the field plate electrodes 33.

The field plate electrodes 33 and the active-region side field plate electrode 33a are covered with the interlayer insulating film 22b (second interlayer insulating film) having a thickness of approximately 500 nm, and the channel stopper electrode 31, the gate line 32, and the upper field plate electrode 39 are electrically isolated from the field plate electrodes 33 and the active-region side field plate electrode 33a by the interlayer insulating film 22b. The interlayer insulating film 22b extends to under the emitter electrode 6 in the IGBT region 10.

The field plate electrodes 33 and the active-region side field plate electrode 33a that are covered with the interlayer insulating film 22b, the channel stopper electrode 31, the gate line 32, and the upper field plate electrode 39 are covered with the silicon nitride film 34 provided as a first protective film and having a thickness of approximately 800 nm. The silicon nitride film 34 extends over the gate line 32 to above the edge portion of the emitter electrode 6 in the IGBT region 10.

On the emitter electrode 6, the solder layer 51 is provided for joining with an external electrode, and the silicon nitride film 34 extends to a position at which it does not come in contact with the solder layer 51. The edge portion of the silicon nitride film 34 on the emitter electrode 6 is formed to be inclined 60 degrees or less toward the surface of the emitter electrode 6.

The upper field plate electrode 39 is formed in the same layer as the channel stopper electrode 31, the gate line 32, and the emitter electrode 6 and, like the collector electrode 7, may be formed of an aluminum alloy or may be formed of an aluminum alloy and a plating film.

Although the upper field plate electrode 39 is arranged between the gate line 32 and the channel stopper electrode 31, the upper field plate electrode 39 is provided at a position that is well away from the gate line 32 because the active-region side field plate electrode 33a is sandwiched between the gate line 32 and the upper field plate electrode 39.

Accordingly, even if the gate line 32 slides in the horizontal direction when the termination region 30 is stressed in the horizontal direction due to expansion and contraction of the sealing resin used to seal the RC-IGBT 106 and when the termination region 30 is stressed in the horizontal direction from the solder layer 51 due to heating of the solder layer 51 for joining with an external electrode, the reliability of the RC-IGBT 106 as a semiconductor device will not decrease because the gate line 32 and the upper field plate electrode 39 are less likely to come in contact with each other.

Besides, the two-layer field plate configured by the active-region side field plate electrode 33a and each of the upper field plate electrode 39 and the field plate electrode 33 more reliably stabilizes the potential in the termination region 30.

Moreover, covering the termination region 30 with the silicon nitride film 34 suppresses a reduction in withstand voltage in further suppresses a reduction in breakdown voltage caused by moisture ingress from the outside.

Since the silicon nitride film 34 has an inclined edge portion, the horizontal stress applied to the silicon nitride film 34 is dispersed in the horizontal and vertical directions, i.e., the X and Y directions. This alleviates the stress applied to the silicon nitride film 34.

### Embodiment 7

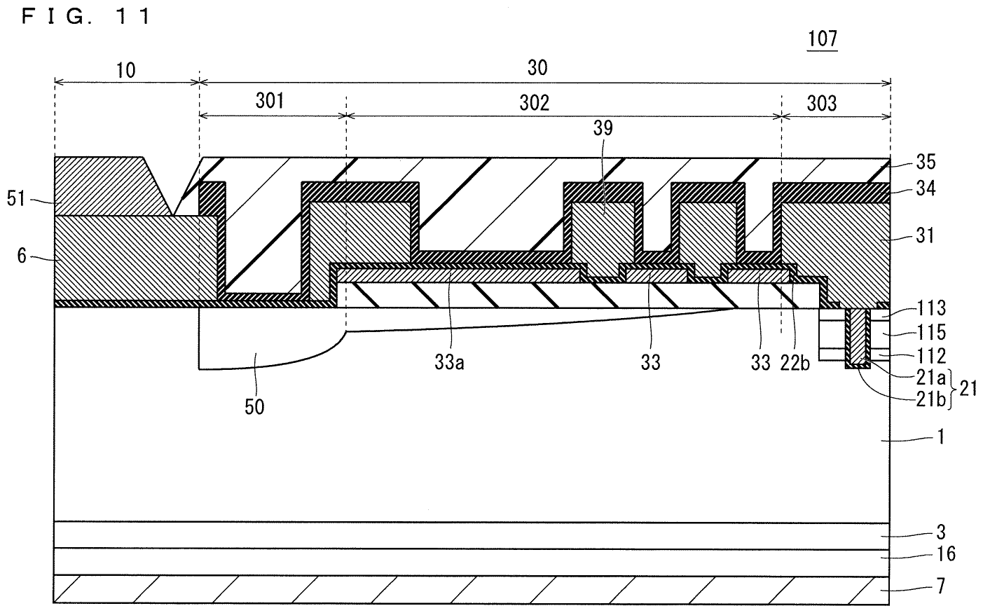

FIG. 11 is a sectional view showing a configuration of an RC-TGBT 107 according to Embodiment 7 and corresponds to the sectional view taken in the direction of the arrow indicated by the broken line A-A in FIG. 1. In the RC-IGBT 107, as shown in FIG. 11, the polyimide film 35 having a thickness of approximately 9 μm is provided as a second protective film to cover over the silicon nitride film 34. In FIG. 11, constituent elements that are identical to those of the RC-IGBT 106 described with reference to FIG. 10 are given the same reference signs, and redundant descriptions thereof shall be omitted.

The polyimide film 35 extends to above the edge portion of the emitter electrode 6 and is formed to be inclined 60 degrees or less toward the surface of the emitter electrode 6.

Like the RC-IGBT 101 according to Embodiment 1, the RC-IGBT 107 also achieves the effect of suppressing a reduction in reliability as a semiconductor device even if stressed in the horizontal direction stress is applied. In conjunction with this, the termination region 30 further covered with the polyimide film 35 improves adhesion to the sealing resin used to seal the RC-IGBT 107 and improves the reliability of the RC-IGBT 107 as a semiconductor device.

Since the polyimide film 35 has an inclined edge portion on the emitter electrode 6, the horizontal stress applied to the polyimide film 35 is dispersed in the horizontal and vertical directions, i.e., the X and Y directions. This alleviates the stress applied to the polyimide film 35.

As described in Embodiment 2, at the same time when the gate trench electrode 11a is formed in the IGBT region 10, the field plate electrodes 33 and the active-region side field plate electrode 33a are formed in the termination region 30.

In the case where the field plate electrodes 33 and the active-region side field plate electrode 33a are formed of polysilicon and the emitter electrode 6 is formed of an aluminum alloy or the like, the field plate electrodes 33 and the active-region side field plate electrode 33a have Young's moduli of approximately 130 GPa, and the emitter electrode 6 has a Young's modulus of approximately 60 GPa. Since the field plate electrodes 33 and the active-region side field plate electrode 33a have higher Young's moduli than the emitter electrode 6, the field plate electrodes 33 and the active-region side field plate electrode 33a become more resistant to deformation caused by external stress.

### Embodiment 8

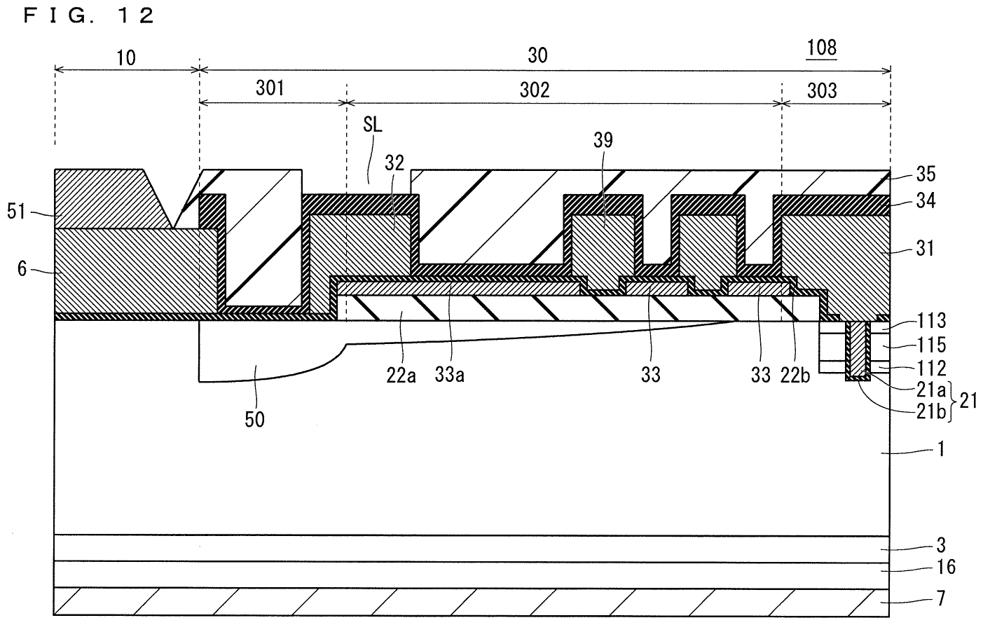

FIG. 12 is a sectional view showing a configuration of an RC-IGBT 108 according to Embodiment 8 and corresponds to the sectional view taken in the direction of the arrow indicated by the broken line A-A in FIG. 1. In the RC-IGBT 108, as shown in FIG. 12, a slit SL is formed in the polyimide film 35 above the gate line 32. In FIG. 12, constituent elements that are identical to those of the RC-IGBT 107 described with reference to FIG. 11 are given the same reference signs, and redundant descriptions thereof shall be omitted.

The slit SL has a width equivalent to the width of the gate line 32 and is formed by opening the polyimide film 35 above the gate line 32 by etching or any other technique so as not to open the silicon nitride film 34. Although the slit SL in FIG. 12 has a width equivalent to the width of the gate line 32, the width of the slit SL may be set in the range of approximately 50 μm to 70 μm that are magnitudes allowing for stable formation during a manufacturing process, but may be set to a greater value.

The presence of the slit SL alleviates the horizontal stress applied from the side of the IGBT region 10, i.e., the active region side, to the polyimide film 35 and in particular the stress applied from the solder layer 51, and improves the reliability of the polyimide film 35. The provision of the slit SL above the gate line 32 improves the reliability of the RC-IGBT 108 as a semiconductor device while the active-region side field plate electrode 33a is protected by the polyimide film 35 and the silicon nitride film 34.

### Variation 1

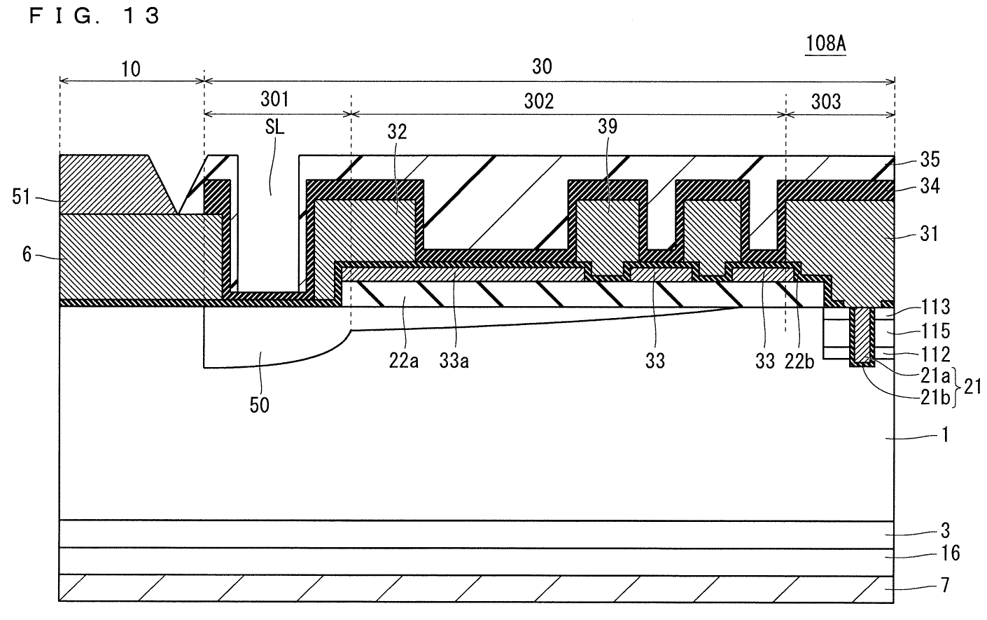

FIG. 13 is a sectional view showing a configuration of an RC-IGBT 108A according to Variation 1 of Embodiment 8 and corresponds to the sectional view taken in the direction of the arrow indicated by the broken line A-A in FIG. 1. In the RC-IGBT 108A, as shown in FIG. 13, the slit SL is formed in the polyimide film 35 provided in the region between the gate line 32 and the emitter electrode 6.

The slit SL has a width that does not exceed over the region between the gate line 32 and the emitter electrode 6 and is formed by opening the polyimide film 35 so as not to open the silicon nitride film 34. The width of the slit SL is adjusted to the interval between the gate line 32 and the emitter electrode 6 and may be set in the range of approximately 50 μm to 70 μm, but may also be increased along with an increase in the interval between the gate line 32 and the emitter electrode 6.

The presence of the slit SL alleviates the horizontal stress applied from the side of the IGBT region 10, i.e., the active region side, to the polyimide film 35 and in particular the stress applied from the solder layer 51, and improves the reliability of the polyimide film 35. The provision of the slit SL in the region other than the region where the active-region side field plate electrode 33a is provided improves the reliability of the RC-IGBT 108A as a semiconductor device while the active-region side field plate electrode 33a is protected by the polyimide film 35 and the silicon nitride film 34 and.

### Variation 2

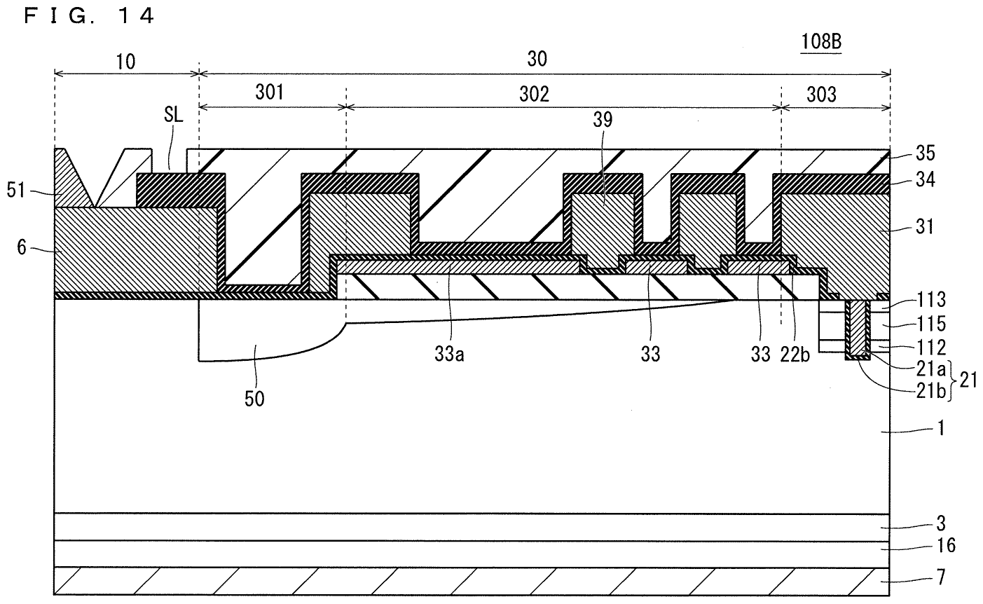

FIG. 14 is a sectional view showing a configuration of an RC-IGBT 108B according to Variation 2 of Embodiment 8 and corresponds to the sectional view taken in the direction of the arrow indicated by the broken line A-A in FIG. 1. In the RC-IGBT 108B, as shown in FIG. 14, the silicon nitride film 34 extends over the edge portion of the emitter electrode 6 in the IGBT region 10, i.e., the active region, and the polyimide film 35 is further provided to cover over the silicon nitride film 34. The slit SL is formed in the polyimide film 35 above the emitter electrode 6.

The slit SL is formed by opening the polyimide film 35 above the silicon nitride film 34 so as not to open the silicon nitride film 34. The width of the slit SL may be set in the range of approximately 50 μm to 70 μm that are magnitudes allowing for stable formation during a manufacturing process, but may also be set to a greater value. In that case, the emitter electrode 6 is further extended on the silicon nitride film 34.

The presence of the slit SL alleviates the horizontal stress applied from the side of the IGBT region 10, i.e., the active region side, to the polyimide film 35 and in particular the stress applied from the solder layer 51, and improves the reliability of the polyimide film 35. Besides, the provision of the slit SL in the region other than the region where the active-region side field plate electrode 33a is provided improves the reliability of the RC-IGBT 108B as a semiconductor device while the active-region side field plate electrode 33a is protected by the polyimide film 35 and the silicon nitride film 34.

### Embodiment 9

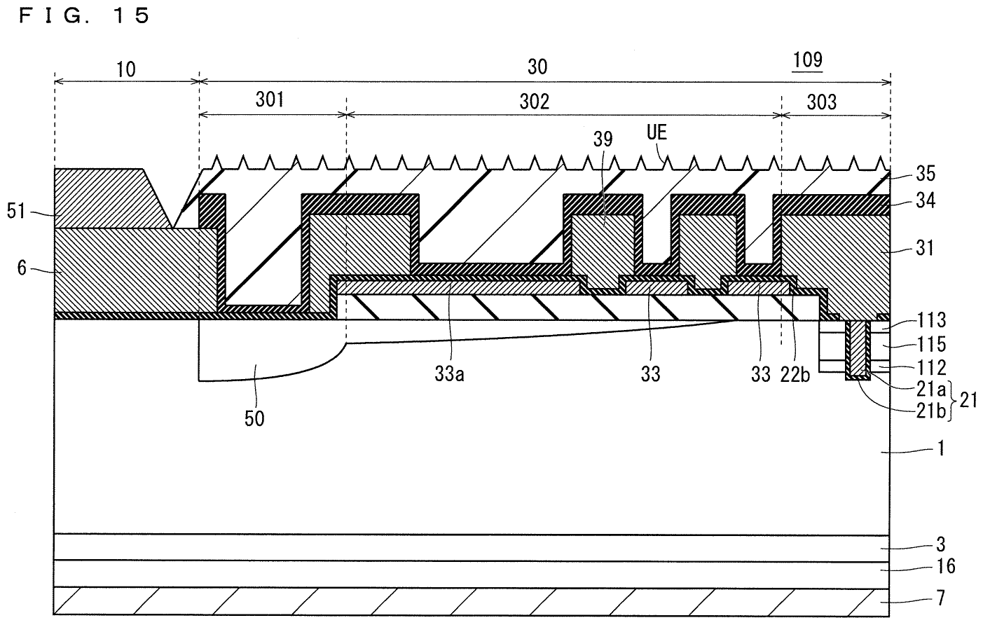

FIG. 15 is a sectional view showing a configuration of an RC-IGBT 109 according to Embodiment 9 and corresponds to the sectional view taken in the direction of the arrow indicated by the broken line A-A in FIG. 1. In the RC-IGBT 109, as shown in FIG. 15, a plurality of projections UE are formed on the surface of the polyimide film 35. In FIG. 15, constituent elements that are identical to those of the RC-IGBT 107 described with reference to FIG. 11 are given the same reference signs, and redundant descriptions thereof shall be omitted.

The projections UE project to a height of approximately 10 nm from the surface of the polyimide film 35, so that the polyimide film 35 has an uneven surface. When the RC-IGBT 109 is sealed with a sealing resin, the presence of the projections UE improves the adhesion of the polyimide film 35 with the sealing resin. This reduces the occurrence of clearance between the sealing resin and the polyimide film 35 and improves the reliability of the RC-IGBT 109 as a semiconductor device.

The uneven surface of the polyimide film 35 is formed because the process performed on the rear surface of the RC-IGBT 109 involves the process of cleaning the front surface, and this cleaning process roughens the surface of the polyimide film 35 and produces irregularities on the surface of the polyimide film 35.

### Embodiment 10

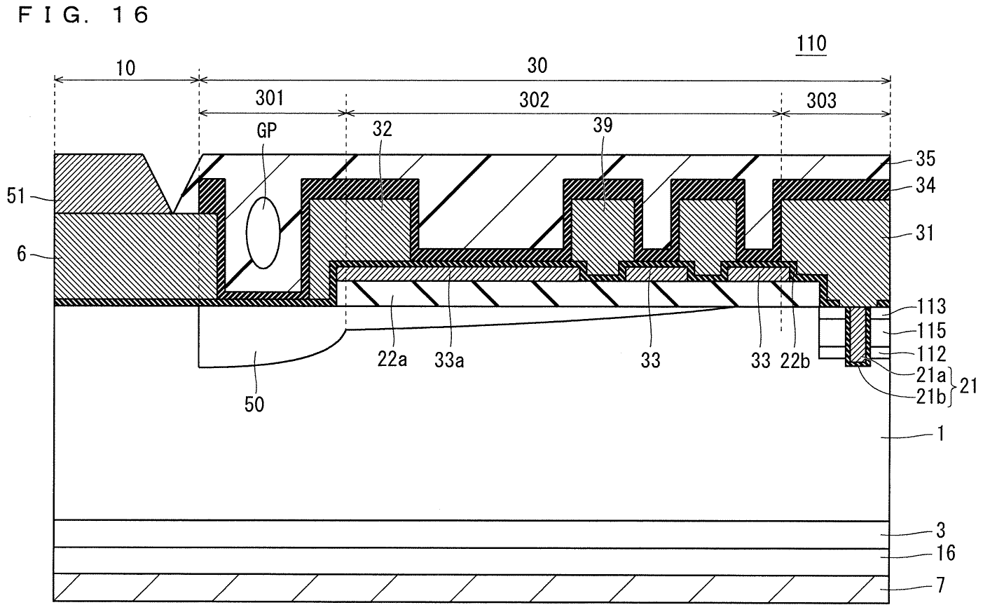

FIG. 16 is a sectional view showing a configuration of an RC-IGBT 110 according to Embodiment 10 and corresponds to the sectional view taken in the direction of the arrow indicated by the broken line A-A in FIG. 1. In the RC-IGBT 110, as shown in FIG. 16, a cavity GP is formed in the polyimide film 35 provided in the region between the gate line 32 and the emitter electrode 6.

The cavity GP has a width that does not exceed across the region between the gate line 32 and the emitter electrode 6 even at its maximum, and is formed in the polyimide film 35 so as not reach to the silicon nitride film 34. The maximum width of the cavity GP is adjusted to the interval between the gate line 32 and the emitter electrode 6 and may be set in the range of approximately 50 μm to 70 μm, but may also be increased along with an increase in the interval between the gate line 32 and the emitter electrode 6.

The provision of the cavity GP alleviates the horizontal stress applied from the side of the IGBT region 10, i.e., the active region side, to the polyimide film 35 and in particular the stress applied from the solder layer 51, and improves the reliability of the polyimide film 35.

The provision of the cavity GP in the region other than the region where the active-region side field plate electrode 33a is provided improves the reliability of the RC-IGBT 110 as a semiconductor device while the active-region side field plate electrode 33a is protected by the polyimide film 35 and the silicon nitride film 34.

In the formation of the cavity GP, after the polyimide film 35 is formed to cover the silicon nitride film 34, an opening is formed by removing part of the polyimide film 35 where the cavity GP is to be formed, by etching or any other technique without penetrating the polyimide film 35. At this time, the conditions of etching may desirably be set such that the upper end of the opening becomes narrower than the bottom of the opening. Thereafter, the polyimide film 35 as a whole is heated and cured at a temperature of approximately 350° C., and the upper end of the opening is closed so as to form the cavity GP in the polyimide film 35.

### Variation of Field Plate Electrodes

In Embodiments 1 to 10 described above, the field plate electrodes 33 and the active-region side field plate electrode 33a have rectangular sectional shapes, but the present disclosure is not limited to this example.

For example, the field plate electrodes 33 and the active-region side field plate electrode 33a may have a trapezoidal sectional shape as shown in FIG. 17. This makes the structure more resistant to deformation caused by external stress.

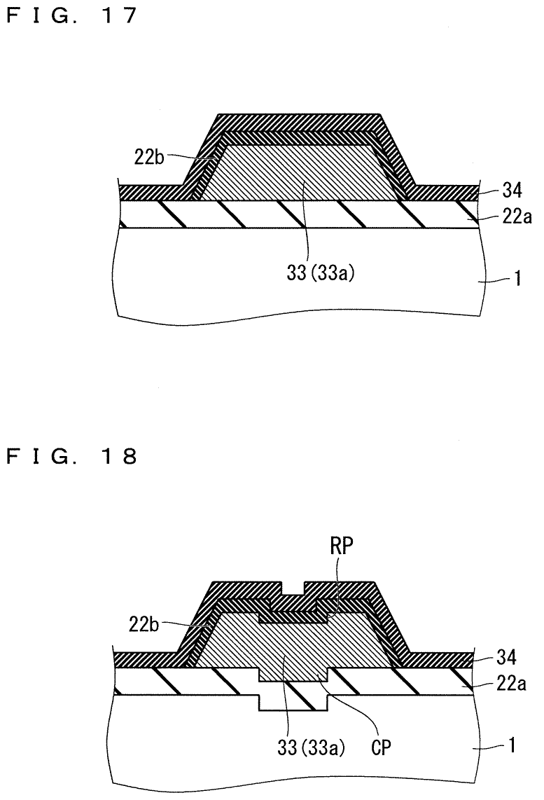

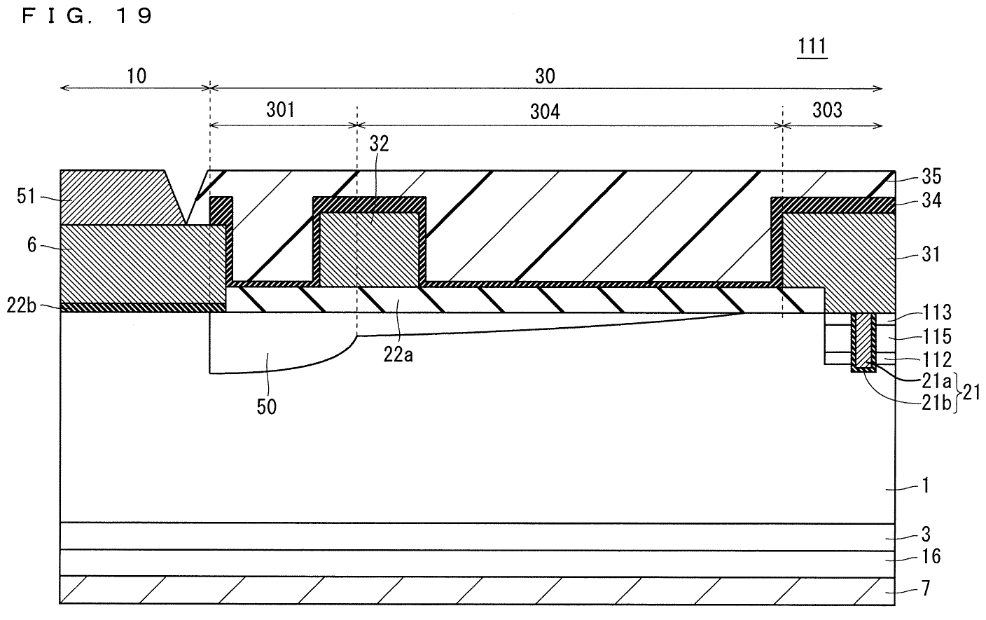

As an alternative, the field plate electrodes 33 and the active-region side field plate electrode 33a of a trapezoidal shape may be shaped to have a recessed portion RP in part of the upper surface and a raised portion CP in part of the bottom surface as shown in FIG. 18. The recessed portion RP and the raised portion CP achieve an anchor effect and make the structure more resistant to deformation caused by external stress.

### Embodiment 11

FIG. 19 is a sectional view showing a configuration of an RC-IGBT 111 according to Embodiment 11 and corresponds to the sectional view taken in the direction of the arrow indicated by the broken line A-A in FIG. 1. In the termination region 30 of the RC-IGBT 111, as shown in FIG. 19, the interlayer insulating film 22a having a thickness of approximately 900 nm is provided on the first main surface of the semiconductor substrate, and the channel stopper electrode 31 and the gate line 32 are provided on the interlayer insulating film 22a. As shown in FIG. 19, the termination region 30 is sectioned into the field relieving region 301, an electrodeless region 304, and the channel stopper region 303 in order from the side closer to the IGBT region 10.

Part of the channel stopper electrode 31 is connected to the trench electrode 21a via a contact hole provided in the interlayer insulating film 22a.

The channel stopper electrode 31 and the gate line 32 are covered with the silicon nitride film 34 provided as a first protective film and having a thickness of approximately 800 nm. The silicon nitride film 34 extends over the gate line 32 to above the edge portion of the emitter electrode 6 in the IGBT region 10.

The polyimide film 35 having a thickness of approximately 9 μm is further provided as a second protective film to cover over the silicon nitride film 34. In FIG. 19, constituent elements that are identical to those of the RC-IGBT 101 described with reference to FIG. 2 are given the same reference signs, and redundant descriptions thereof shall be omitted.

The polyimide film 35 extends to above the edge portion of the emitter electrode 6 and is formed to be inclined 60 degrees or less toward the surface of the emitter electrode 6.

In the RC-IGBT 111, no electrodes are provided on the entire region between the channel stopper electrode 31 and the gate line 32. Accordingly, even if the gate line slides in the horizontal direction when the termination region 30 is stressed in the horizontal direction due to expansion and contraction of a sealing resin used to seal the RC-IGBT 111 and when the termination region 30 is stressed in the horizontal direction from the solder layer 51 due to heating of the solder layer 51 for joining with an external electrode, the reliability of the RC-IGBT 111 will not decrease because there are no electrodes that come in contact with the gate line 32.

Besides, since the polyimide film 35 has an inclined edge portion on the emitter electrode 6, horizontal stress applied to the polyimide film 35 is dispersed in the horizontal and vertical directions, i.e., the X and Y directions. This alleviates the stress applied to the polyimide film 35.

Note that the slit SL described in Embodiment 3 with reference to FIGS. 5 to 7 may be provided in the polyimide film 35 of the RC-IGBT 111.

As another alternative, the projections UE described in Embodiment 4 with reference to FIG. 8 may be provided on the surface of the polyimide film 35 of the RC-IGBT 111 to make uneven the surface of the polyimide film 35.

As yet another alternative, the cavity GP described in Embodiment 5 with reference to FIG. 9 may be provided in the polyimide film 35 of the RC-IGBT 111.

It should be noted that the present disclosure can be implemented by freely combining the embodiments or making modifications or omissions on the embodiments as appropriate without departing from the scope of the present disclosure.

The present disclosure described above is described as appendixes in summary.

### Appendix 1

A semiconductor device includes a transistor formed on a semiconductor substrate. The semiconductor substrate includes an active region in which the transistor is formed, and a termination region surrounding the active region. The termination region includes an first interlayer insulating film provided on the semiconductor substrate, a second interlayer insulating film provided on the first interlayer insulating film, a wiring electrode electrically connected to a gate electrode of the transistor, a terminal electrode provided closer to an edge portion of the semiconductor substrate than the wiring electrode is, and a field plate electrode provided between the wiring electrode and the terminal electrode in plan view. The wiring electrode, the field plate electrode, and the terminal electrode are provided on the first interlayer insulating film. The field plate electrode is covered with the second interlayer insulating film. The wiring electrode, the field plate electrode covered with the second interlayer insulating film, and the terminal electrode are covered with a protective film. The field plate electrode has a smaller height than the wiring electrode and the terminal electrode.

### Appendix 2

A semiconductor device includes a transistor formed on a semiconductor substrate. The semiconductor substrate includes an active region in which the transistor is formed, and a termination region surrounding the active region. The termination region includes a first interlayer insulating film provided on the semiconductor substrate, a second interlayer insulating film provided on the first interlayer insulating film, a wiring electrode electrically connected to a gate electrode of the transistor, a terminal electrode provided closer to an edge portion of the semiconductor substrate than the wiring electrode is, a plurality of field plate electrodes provided between the wiring electrode and the terminal electrode in plan view, and an upper field plate electrode provided closer to the terminal electrode than the wiring electrode is. The wiring electrode, the plurality of field plate electrodes, and the terminal electrode are provided on the first interlayer insulating film. The plurality of field plate electrodes are covered with the second interlayer insulating film. The upper field plate electrode is provided on the second interlayer insulating film. The plurality of field plate electrodes includes an active-region side field plate electrode that is located closest to the active region and that has a greater width than the other field plate electrodes. The wiring electrode, the plurality of field plate electrodes covered with the second interlayer insulating film, the upper field plate electrode, and the terminal electrode are covered with a protective film. The plurality of field plate electrodes have a smaller height than the wiring electrode and the terminal electrode.

### Appendix 3

A semiconductor device includes a transistor formed on a semiconductor substrate. The semiconductor substrate includes an active region in which the transistor is formed, and a termination region surrounding the active region. The termination region includes an interlayer insulating film provided on the semiconductor substrate, a wiring electrode electrically connected to a gate electrode of the transistor, and a terminal electrode provided closer to an edge portion of the semiconductor substrate than the wiring electrode is. The wiring electrode and the terminal electrode are provided on the interlayer insulating film. The wiring electrode, the terminal electrode, and the interlayer insulating film provided between the wiring electrode and the terminal electrode are covered with a protective film.

### Appendix 4

In the semiconductor device according to any one of Appendixes 1 to 3, the protective film includes a silicon nitride film.

### Appendix 5

In the semiconductor device according to Appendix 4, the protective film includes a polyimide film that covers the silicon nitride film.

### Appendix 6

In the semiconductor device according to Appendix 5, the polyimide film has a slit provided between the wiring electrode and the active region.

### Appendix 7

In the semiconductor device according to Appendix 5, the polyimide film has an uneven surface provided with a plurality of projections.

### Appendix 8

In the semiconductor device according to Appendix 5, the polyimide film includes a cavity provided between the wiring electrode and the active region.

### Appendix 9

In the semiconductor device according to Appendix 1, the field plate electrode has a height of less than or equal to 1 μm.

### Appendix 10

In the semiconductor device according to Appendix 1, the field plate electrode has a higher Young's modulus than a main electrode of the transistor provided in the active region.

### Appendix 11

In the semiconductor device according to Appendix 1, the field plate electrode is formed of polysilicon or amorphous silicon.

### Appendix 12

In the semiconductor device according to Appendix 1, the field plate electrode has a trapezoidal sectional shape.

### Appendix 13

In the semiconductor device according to Appendix 12, the field plate electrode has an upper surface provided with a recessed portion and a bottom surface provided with a raised portion.

### Appendix 14

In the semiconductor device according to Appendix 2, the plurality of field plate electrodes have a height of less than or equal to 1 km.

### Appendix 15

In the semiconductor device according to Appendix 1, the plurality of field plate electrodes, each being the field plate electrode, have a higher Young's modulus than a main electrode of the transistor provided in the active region.

### Appendix 16

In the semiconductor device according to Appendix 1, the plurality of field plate electrodes are formed of polysilicon or amorphous silicon.

### Appendix 17

In the semiconductor device according to any one of Appendixes 1 to 3, the protective film has an inclined end portion on a side of the active region, the inclined end portion being inclined 60 degrees or less.

### Appendix 18

In the semiconductor device according to Appendix 1, the field plate electrode has a trapezoidal sectional shape.

### Appendix 19

In the semiconductor device according to Appendix 18, the field plate electrode has an upper surface provided with a recessed portion and a bottom surface provided with a raised portion.

While the present disclosure has been shown and described in detail, the foregoing description is in all aspects illustrative and not restrictive. It is therefore understood that numerous modifications and variations can be devised without departing from the scope of the present disclosure.

What is claimed is:

1. A semiconductor device including a transistor formed on a semiconductor substrate,
the semiconductor substrate including:
an active region in which the transistor is formed; and
a termination region surrounding the active region,
the termination region including:
an first interlayer insulating film provided on the semiconductor substrate;
a second interlayer insulating film provided on the first interlayer insulating film;
a wiring electrode electrically connected to a gate electrode of the transistor;
a terminal electrode provided closer to an edge portion of the semiconductor substrate than the wiring electrode is; and
a field plate electrode provided between the wiring electrode and the terminal electrode in plan view,
wherein the wiring electrode, the field plate electrode, and the terminal electrode are provided on the first interlayer insulating film,
the field plate electrode is covered with the second interlayer insulating film,
the wiring electrode, the field plate electrode covered with the second interlayer insulating film, and the terminal electrode are covered with a protective film, and
the field plate electrode has a smaller height than the wiring electrode and the terminal electrode.

2. The semiconductor device according to claim 1, wherein
the protective film includes a silicon nitride film.

3. The semiconductor device according to claim 2, wherein
the protective film includes a polyimide film that covers the silicon nitride film.

4. The semiconductor device according to claim 3, wherein
the polyimide film has a slit provided between the wiring electrode and the active region.

5. The semiconductor device according to claim 3, wherein
the polyimide film has an uneven surface provided with a plurality of projections.

6. The semiconductor device according to claim 3, wherein
the polyimide film includes a cavity provided between the wiring electrode and the active region.

7. The semiconductor device according to claim 1, wherein
the field plate electrode has a height of less than or equal to 1 μm.

8. The semiconductor device according to claim 1, wherein
the field plate electrode has a higher Young's modulus than a main electrode of the transistor provided in the active region.

9. The semiconductor device according to claim 1, wherein
the field plate electrode is formed of polysilicon or amorphous silicon.

10. The semiconductor device according to claim 1, wherein
the field plate electrode has a trapezoidal sectional shape.

11. The semiconductor device according to claim 10, wherein
the field plate electrode has an upper surface provided with a recessed portion and a bottom surface provided with a raised portion.

12. The semiconductor device according to claim 1, wherein
a plurality of field plate electrodes, each being the field plate electrode, have a higher Young's modulus than a main electrode of the transistor provided in the active region.

13. The semiconductor device according to claim 1, wherein
a plurality of field plate electrodes, each being the field plate electrode, is formed of polysilicon or amorphous silicon.

14. The semiconductor device according to claim 1, wherein
the protective film has an inclined end portion of the active region side, the inclined end portion being inclined 60 degrees or less.

15. The semiconductor device according to claim 1, wherein
the field plate electrode has a trapezoidal sectional shape.

16. The semiconductor device according to claim 15, wherein
the field plate electrode has an upper surface provided with a recessed portion and a bottom surface provided with a raised portion.

17. A semiconductor device including a transistor formed on a semiconductor substrate,
the semiconductor substrate including:
an active region in which the transistor is formed; and
a termination region surrounding the active region,
the termination region including:
a first interlayer insulating film provided on the semiconductor substrate;
a second interlayer insulating film provided on the first interlayer insulating film;
a wiring electrode electrically connected to a gate electrode of the transistor;
a terminal electrode provided closer to an edge portion of the semiconductor substrate than the wiring electrode is;
a plurality of field plate electrodes provided between the wiring electrode and the terminal electrode in plan view; and
an upper field plate electrode provided closer to the terminal electrode than the wiring electrode is,
wherein the wiring electrode, the plurality of field plate electrodes, and the terminal electrode are provided on the first interlayer insulating film,
the plurality of field plate electrodes are covered with the second interlayer insulating film,
the upper field plate electrode is provided on the second interlayer insulating film,
the plurality of field plate electrodes includes an active-region side field plate electrode that is located closest to the active region and that has a greater width than the other field plate electrodes,
the wiring electrode, the plurality of field plate electrodes covered with the second interlayer insulating film, the upper field plate electrode, and the terminal electrode are covered with a protective film, and
the plurality of field plate electrodes have a smaller height than the wiring electrode and the terminal electrode.

18. The semiconductor device according to claim 17, wherein
the protective film includes a silicon nitride film.

19. The semiconductor device according to claim 18, wherein
the protective film includes a polyimide film that covers the silicon nitride film.

20. The semiconductor device according to claim 19, wherein
the polyimide film has a slit provided between the wiring electrode and the active region.

21. The semiconductor device according to claim 19, wherein
the polyimide film has an uneven surface provided with a plurality of projections.

22. The semiconductor device according to claim 19, wherein
the polyimide film includes a cavity provided between the wiring electrode and the active region.

23. The semiconductor device according to claim 17, wherein
the plurality of field plate electrodes have a height of less than or equal to 1 μm.

24. The semiconductor device according to claim 17, wherein
the protective film has an inclined end portion of the active region side, the inclined end portion being inclined 60 degrees or less.

25. A semiconductor device including a transistor formed on a semiconductor substrate,
the semiconductor substrate including:
an active region in which the transistor is formed; and
a termination region surrounding the active region,
the termination region including:
an interlayer insulating film provided on the semiconductor substrate;
a wiring electrode electrically connected to a gate electrode of the transistor; and
a terminal electrode provided closer to an edge portion of the semiconductor substrate than the wiring electrode is,
wherein the wiring electrode and the terminal electrode are provided on the interlayer insulating film,
the wiring electrode, the terminal electrode, and the interlayer insulating film provided between the wiring electrode and the terminal electrode are covered with a protective film.

26. The semiconductor device according to claim 25, wherein
the protective film includes a silicon nitride film.

27. The semiconductor device according to claim 26, wherein
the protective film includes a polyimide film that covers the silicon nitride film.

28. The semiconductor device according to claim 27, wherein
the polyimide film has a slit provided between the wiring electrode and the active region.

29. The semiconductor device according to claim 27, wherein
the polyimide film has an uneven surface provided with a plurality of projections.

30. The semiconductor device according to claim 27, wherein
the polyimide film includes a cavity provided between the wiring electrode and the active region.

31. The semiconductor device according to claim 25, wherein
the protective film has an inclined end portion of the active region side, the inclined end portion being inclined 60 degrees or less.
